(19) United States
(12) Patent Application Publication
(10) Pub. No.: US 2025/0226358 A1
(43) Pub. Date: Jul. 10, 2025

(54) PRE-ATTACHED ENGINEERED SOLDERS FOR ULTRA-LOW RESIDUE SOLDERING

(71) Applicant: THE INDIUM CORPORATION OF AMERICA, Clinton, NY (US)

(72) Inventors: Joseph M. Hertline, Marcy, NY (US); David P. Socha, Whitesboro, NY (US)

(21) Appl. No.: 19/012,500

(22) Filed: Jan. 7, 2025

Related U.S. Application Data
(60) Provisional application No. 63/618,800, filed on Jan. 8, 2024.

(51) Int. Cl. H01L 23/00

(52) U.S. Cl. CPC H01L 24/81; H01L 2224/81201; H01L 2224/81815

(57) ABSTRACT

Some implementations of the disclosure are directed to a method including: placing a first solder preform and a first tacky material between a first device and a second device to form a semiconductor assembly, the first tacky material configured to cause a surface of the first device to adhere to a first surface of the first solder preform, and a first surface of the second device to adhere to a second surface of the first solder preform opposite the first surface; and reflowing the semiconductor assembly at a temperature above a solidus temperature of the first solder preform to bond, via at least the first solder preform, the first device to the second device. The first tacky material has a reflow residual weight of less than 1% of the weight of the first tacky material before reflowing the semiconductor assembly.

### CROSS-REFERENCE TO RELATED APPLICATIONS

The present application claims the benefit of U.S. Provisional Patent Application No. 63/618,800 filed on Jan. 8, 2024, and titled “PRE-ATTACHED ENGINEERED SOLDERS FOR ULTRA-LOW RESIDUE SOLDERING,” which is incorporated herein by reference in its entirety.

### DESCRIPTION OF THE RELATED ART

Manufacturing processes of soldered and sintered power modules have strong influence on costs, reliability, and lifetime of the products. The adoption and accelerated growth of electric vehicles in recent years has led to an exponential growth in power module packaging. Semiconductor packagers are looking for innovative ways to keep up with demand. Reliance on complex, costly alignment tooling is growing as power module designers seek improved reliability performance.

High-powered semiconductor dies required for power modules produce excess heat that must be transferred away from the semiconductor die. Heat is produced at the semiconductor die and flows through the assembly, away from the die, to the base plate. A thermal interface material can facilitate the transfer of heat towards the base plate.

For high power, high performance, semiconductor packaging applications, voiding in the solder joints should be minimized to prevent hot spots which could prematurely degrade the die. Solder paste is comprised of solder powder, flux, a solvent, and a thixotropic agent. The use of solder paste in these applications can cause voiding as the solvent is driven off during the reflow process. Furthermore, volatile components in the solder paste can coat the inside of the oven during reflow causing frequent stops in production to clean the oven. After reflowing, if the volatile components of the solder paste are not driven off during the reflow process, the fluxing agent can leave a residue on the printed circuit board (PCB) that may cause short circuits.

One method to prevent excess voiding during the reflow process is to use a solid, pre-shaped solder preform as an alternative attachment method to solder paste. Often, the solder preform may still need to be coated with a liquid flux to remove oxides that could prevent wetting. In this case, the liquid flux can leave an undesired residue on the PCB or on the parts being joined which will need to be cleaned prior to placing the module in service.

The use of liquid fluxes to coat the surfaces of solid, solder preforms during reflow can also contaminate the interior surfaces of the reflow oven. Periodically, the oven must be removed from service to clean these flux residues from the interior surfaces of the reflow oven, during which no assemblies can be produced. If flux residue remains on the final assembly following reflow and a cleaning step, this residue can bridge components or connections and cause short circuits or catastrophic failure of the device while in service.

When fixturing is required to hold the assembly together during reflow, the bulky fixturing can prevent the reducing atmosphere during reflow from penetrating the assembly to clean the oxides from the surfaces to be joined. In addition, the fixturing requires a footprint within the reflow oven that limits the number of devices that can be reflowed in a single batch. The fixturing also acts as a heat sink requiring longer heating times for the reflow oven to reach peak temperature.

Another concern while reflowing the die to the substrate is improper alignment. This can lead to die tilt which can be observed when an uneven bond line between the die and the Direct Bonded Copper (DBC) occurs following reflow. Other potential defects in the solder joint include mechanical stress, uneven heat transfer, and thermal stress which can result in delamination failures and reduced lifetime.

### SUMMARY

The technology described herein is directed to ultra-low residue soldering systems and methods.

In one embodiment, a method comprises: placing a first solder preform and a first tacky material between a first device and a second device to form a semiconductor assembly, the first tacky material configured to cause a surface of the first device to adhere to a first surface of the first solder preform, and a first surface of the second device to adhere to a second surface of the first solder preform opposite the first surface; and reflowing the semiconductor assembly at a temperature above a solidus temperature of the first solder preform to bond, via at least the first solder preform, the first device to the second device, wherein the first tacky material has a reflow residual weight of less than 1% of a weight of the first tacky material before reflowing the semiconductor assembly.

In some implementations, the first device is a semiconductor die; and the first tacky material is placed between the first solder preform and the semiconductor die.

In some implementations, the second device is a DBC or baseplate; and the first tacky material is placed between the first solder preform and the DBC or baseplate.

In some implementations, the first device is a DBC; and the first tacky material is placed between the first solder preform and the DBC.

In some implementations, the first device is a baseplate; and the first tacky material is placed between the first solder preform and the baseplate.

In some implementations, the method further comprises: prior to reflowing the semiconductor assembly, applying pressure to the semiconductor assembly to cause the surface of the first device to adhere, via the first tacky material, to the first surface of the first solder preform, and the surface of the second device to adhere, via the first tacky material, to the second surface of the solder preform.

In some implementations, reflowing the semiconductor assembly comprises: reflowing the semiconductor assembly without a mechanical fixture that holds together the semiconductor assembly.

In some implementations, reflowing the semiconductor assembly comprises heating the semiconductor assembly in the presence of an inert gas or reducing gas.

In some implementations, the inert gas or reducing gas comprises nitrogen, argon, helium, hydrogen, formic acid, or forming gas.

In some implementations, reflowing the semiconductor assembly comprises heating the first solder preform above its solidus point to metallurgically bond the semiconductor assembly.

In some implementations, reflowing the semiconductor assembly comprises exposing the semiconductor assembly to a heat source of 230° C. or greater for 20 seconds to 240 seconds.

In some implementations, the reflow residual weight of the first tacky material is less than 0.1% of the weight of the first tacky material before reflowing the semiconductor assembly.

In some implementations, the first tacky material is fully consumed during reflow of the semiconductor assembly.

In some implementations, the first tacky material has a viscosity from 6 Kcps to 30 Kcps.

In some implementations, the first tacky material has a tackiness from 260 grams to 410 grams.

In some implementations, reflowing the semiconductor assembly comprises: reflowing the semiconductor assembly without a flux coating on the first solder preform.

In some implementations, reflowing the semiconductor assembly comprises: reflowing the semiconductor assembly with a low-residue flux coating on the first solder preform.

In some implementations, the first solder preform comprises an interior matrix material having a solidus point higher than a solidus point of the first solder preform.

In some implementations, the interior matrix material comprises copper or silver.

In some implementations, the solidus point of the interior matrix material is at least 100° C. greater than the solidus point of the first solder preform.

In some implementations, the solidus point of the interior matrix material is at least 500° C. greater than the solidus point of the first solder preform.

In some implementations, the interior matrix material comprises a coating.

In some implementations, the first solder preform comprises tin, silver, copper, antimony, lead, or indium.

In some implementations, the method further comprises: placing a second solder preform and a second tacky material between the second device and a third device to form the semiconductor assembly, the second tacky material configured to cause a second surface of the second device opposite the first surface of the second device to adhere to a first surface of the second solder preform, and a first surface of third device to adhere to a second surface of the second solder preform opposite the first surface of the second solder preform.

In some implementations, reflowing the semiconductor assembly comprises reflowing the semiconductor assembly at a temperature above the solidus temperature of the first solder preform and above a solidus temperature of the second solder preform to bond, via at least the first solder preform, the first device to the second device, and to bond, via at least the second solder preform, the second device to the third device; and the second tacky material has a reflow residual weight of less than 1% of a weight of the second tacky material before reflowing the semiconductor assembly.

In one embodiment, a method comprises: dispensing a sintering paste on a substrate, the sintering paste comprising a plurality of silver particles or copper particles; after dispensing the sintering paste, drying the sintering paste to form a dried sintering paste; depositing a tacky material on the dried sintering paste; after depositing the tacky material on the dried sintering paste, placing a device on the tacky material to form a semiconductor assembly; and sintering the semiconductor assembly to form a sintering joint bonding the substrate and device.

In one embodiment, a method comprises: applying a thermal interface material (TIM) between a first device and a second device to form a semiconductor assembly having a first surface of the TIM in in touching relation with a surface of the first device, and a second surface of the TIM opposite the first surface in touching relation with a surface of the second device, the TIM comprising a flexible sheet material including a braid layer formed of a plurality of filaments of metal, glass, or polymeric fibers, and first and second layers of indium impressed directly against the braid layer with the braid layer sandwiched therebetween; and applying pressure to the semiconductor assembly to bond, via the flexible sheet material, the first device to the second device.

Other features and aspects of the disclosed technology will become apparent from the following detailed description, taken in conjunction with the accompanying drawings, which illustrate, by way of example, the features in accordance with implementations of the disclosed technology. The summary is not intended to limit the scope of any inventions described herein, which are defined by the claims and equivalents.

It should be appreciated that all combinations of the foregoing concepts (provided such concepts are not mutually inconsistent) are contemplated as being part of the inventive subject matter disclosed herein. In particular, all combinations of claimed subject matter appearing at the end of this disclosure are contemplated as being part of the inventive subject matter disclosed herein.

### BRIEF DESCRIPTION OF THE DRAWINGS

The present disclosure, in accordance with one or more implementations, is described in detail with reference to the following figures. The figures are provided for purposes of illustration only and merely depict example implementations. Furthermore, it should be noted that for clarity and ease of illustration, the elements in the figures have not necessarily been drawn to scale.

Some of the figures included herein illustrate various implementations of the disclosed technology from different viewing angles. Although the accompanying descriptive text may refer to such views as “top,” “bottom” or “side” views, such references are merely descriptive and do not imply or require that the disclosed technology be implemented or used in a particular spatial orientation unless explicitly stated otherwise.

FIG. 1 shows a side view of a semiconductor assembly, in accordance with some implementations of the disclosure.

FIG. 2 shows a top view of the semiconductor assembly of FIG. 1.

FIG. 3 is an operational flow diagram illustrating an example method of assembling a semiconductor assembly with one or more solder preforms and a tacky material, in accordance with some implementations of the disclosure.

FIG. 4 shows an example side view of a semiconductor assembly that bonds a semiconductor die to a substrate using a sintering paste and tacky material, in accordance with some implementations of the disclosure.

The figures are not exhaustive and do not limit the present disclosure to the precise form disclosed.

### DETAILED DESCRIPTION

As described above, there are various defects that can arise from using a solid, pre-shaped solder preform during reflow soldering. These defects can include the undesired residue leftover from the liquid flux used to coat the solder preform, contamination of the reflow oven by the liquid flux, the use of bulky fixturing to hold the semiconductor assembly together during reflow, and/or improper alignment of the semiconductor die to the substrate. Systems and methods described herein are directed to eliminating the above-mentioned defects while streamlining the assembly process and providing greater throughput through the reflow oven. In accordance with some implementations of the disclosure, a no-residue or low-residue adhesive material, applied to the assembly, eliminates the need for customized fixturing tools during soldering. This adhesive can achieve exceptional soldering and sintering results without post-process cleaning steps. It can be compatible with solder preforms and flux-free reflow techniques using a nitrogen environment with or without a reducing atmosphere. As such, by virtue of leveraging this adhesive material technology, substrates, preforms, and other device components can be pre-attached in a package to be assembled at a later time, simplifying the final manufacturing process. These and other implementations are further described below.

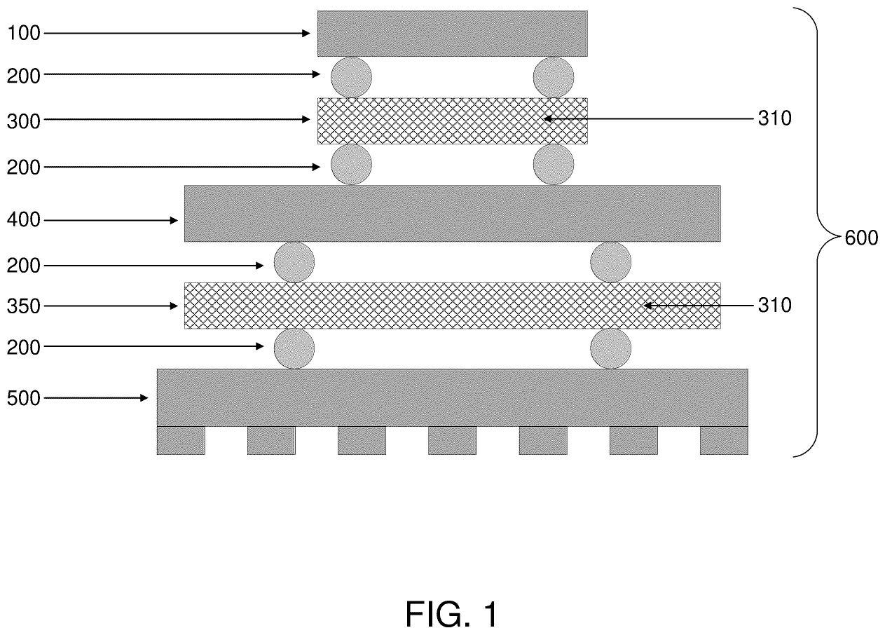

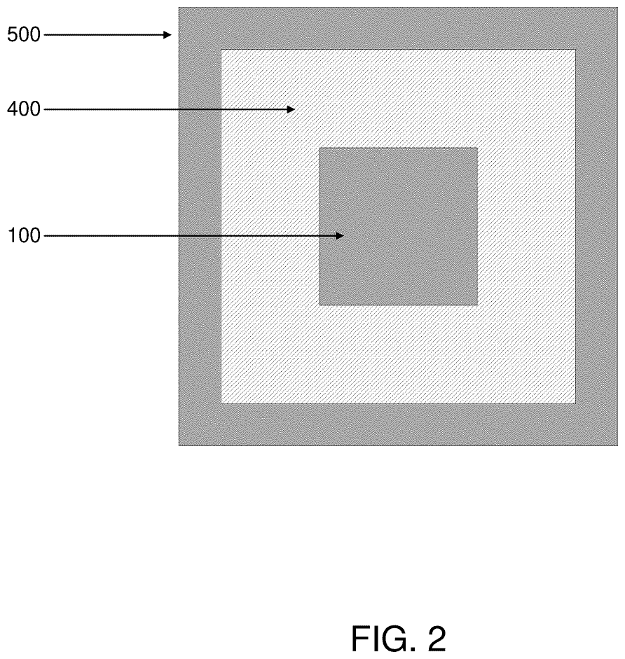

FIGS. 1-2 shows a semiconductor assembly 600, in accordance with some implementations of the disclosure. FIG. 1 shows a side view of semiconductor assembly 600, and FIG. 2 shows a top view of semiconductor assembly 600. The semiconductor assembly can be a component of a power module. The power module can be used in inverters for electric vehicles, wind turbines, solar power panels, or other equipment. It can also be used with equipment for power conversion, including motor drives, power supplies, and the like. The semiconductor assembly 600 could also be a component of other types of modules.

The semiconductor assembly 600 includes semiconductor die 100, DBC layer 400, baseplate 500, tacky material 200 to align and/or fixture the assembly components, solder preform 300 to bond semiconductor die 100 to DBC layer 400, and solder preform 350 to bond DBC layer 400 to baseplate 500. To eliminate or otherwise reduce the need for customized fixturing tools during soldering and assembly of semiconductor assembly 600, semiconductor assembly 600 is assembled using a tacky material 200 that leaves behind no residue or minimal residue, and can be configured to temporarily join and/or align the individual components of semiconductor assembly 600 during reflow.

The tacky material 200 can be comprised of polyglycol ethers and/or alcohols. In some implementations, tacky material 200 has a viscosity range from about 6 Kcps to 30 Kcps. In some implementations, tacky material 200 has a tackiness range from about 260 to about 410 grams. In some implementations, tacky material 200 has a reflow residual weight less than 1% of the weight of the tacky material before reflow. In some implementations, tacky material 200 has a reflow residual weight of less than 0.1%. In some implementations, tacky material 200 has a reflow residual weight of about zero provided that a sufficient reflow peak temperature is sustained for a sufficient amount of time. For example, the reflow residual weight can be zero when the reflow peak temperature is sustained for a range of about 20seconds to 240 seconds. In some implementations, tacky material 200 has a shelf life of greater than 6 months when stored at 0° C.-30° C.

The tacky material 200 can be compatible with dispensing and other methods of deposition. For example, the tacky material 200 can be applied by screen printing, spin coating, jetting, brushing or any other means suitable for coating semiconductor die 100 and other components of the assembly 600 with tacky material 200.

During operation, semiconductor die 100 generates heat that needs to be transferred away from die 100 to maximize its efficiency and longevity. Semiconductor die 100 can be comprised of materials such as silicon, silicon carbide, gallium arsenide, gallium nitride, gallium oxide indium phosphide, or germanium selenide. In some implementations, the semiconductor die 100 can contain a metallization layer. DBC 400 can comprised of a ceramic isolator such as aluminum oxide or aluminum nitride between two pieces of pure copper bonded together when exposed to sufficient temperature. The copper pieces can be bonded to the ceramic by diffusion bonding. A pre-bonded DBC 400 can be obtained prior to assembly of semiconductor assembly 600.

The Solder preforms 300 and 350 are used to metallurgically bond semiconductor assembly 600 together. Solder preforms 300 and 350 can be comprised of tin, silver, copper, antimony, lead, indium, or combinations or alloys thereof. Examples of such compositions include tin-silver-copper-antimony, tin-antimony, and high lead-containing alloys. In some implementations, solder preforms 300 and 350 may be comprised of dissimilar materials.

In some implementations, illustrated by FIGS. 1-2, solder preforms 300 and 350 can contain a matrix material 310 with a solidus point greater than the solidus point of the metal or metal alloy comprising solder preforms 300 and 350. The solidus point of matrix material 310 can be at least 100° C. greater than the solidus point of solder preforms 300 and 350. In some implementations, matrix material 310 can have a solidus point that is at least 500° C. greater than the solidus point of solder preforms 300 and 350. Matrix material 310 may be comprised of copper, silver, or another metal or metal alloy where the material comprising matrix material 310 has a solidus point higher than the solidus point of the metal or metals comprising solder preforms 300 and 350. Interior matrix material 310 can remain solid during reflow. It may be desirable to choose a matrix material 310 of a specific height to maintain a desired bond line thickness distance between the two components being joined.

Matrix material 310 can be in the form of a mesh comprised of wire, braid, ribbon, or foil at which intersecting nodes form the matrix 310 within solder preforms 300 and 350. Matrix material 310 can contain a coating on its outer surface to promote wetting and to prevent void formation. In implementations where matrix material 310 is in the form of a mesh, the distance between the nodes of the mesh can range from 200 microns to 10,000 microns. The width of matrix material 310 forming the mesh can range from 20 microns to several millimeters depending on the overall size of solder preforms 300 and 350. The height of the matrix material 310 can range from 30 microns to 800 microns. In some implementations, the height of the matrix material 310 can range from 50 microns to 250 microns provided that the height within each individual solder preform 300 or 350 is the same to ensure a consistent standoff between the components to be joined. Solder preform 300 or 350 can add an additional 50 microns or more to overall height of the part depending on the total solder volume needed to metallurgically bond the surfaces to be joined. In some implementations, solder preform 300 and/or solder preform 350 does not include a matrix material 310.

During assembly, semiconductor assembly 600 can be temporarily held together with tacky material 200 between each of the layers from the semiconductor die 100 to baseplate 500. Semiconductor die 100 can be held to solder preform 300. Solder preform 300 can be held to the DBC 400. DBC 400 can be held to solder preform 350. Solder preform 350 can be held to baseplate 500. While tacky material 200 may not be configured to provide an electrically conductive or thermally conductive pathway from semiconductor die 100 to baseplate 500, it can hold assembly 600 together, temporarily, without the need for mechanical fixturing during the reflow process. During reflow, in an inert or reducing atmosphere, tacky material 200 can be completely consumed during the reflow process with no residue remaining after an exposure to a sufficiently high temperature (e.g., about 230° C.). Once the temperature of the oven reaches a temperature sufficient to melt solder preform 300 and solder preform 350, assembly 600 can be removed from the oven and allowed to cool below the solidus point of reflowed solder preforms 300 and 350.

Although the illustrated example shows a semiconductor assembly 600 having two TIM layers that transfer heat, including a TIM1 layer (solder preform 300) and a TIM2 layer (solder preform 350), that are used in conjunction with tacky material 200, it should be appreciated that the technology described herein could be utilized with other semiconductor assemblies. The technology described herein could be used with semiconductor assemblies having a single TIM. For example, a solder preform could be used as a TIM0 layer that transfers heat generated by a semiconductor die to a heat sink. In such arrangements, a tacky material could be deposited on both sides of the TIM0 layer and/or the components that it is coupled to. In addition, although the illustrated example is described in the context of applying tacky material 200 to both TIM layers (solder preform 300 or 350), in some implementations the tacky material can be applied to only one of the TIM layers.

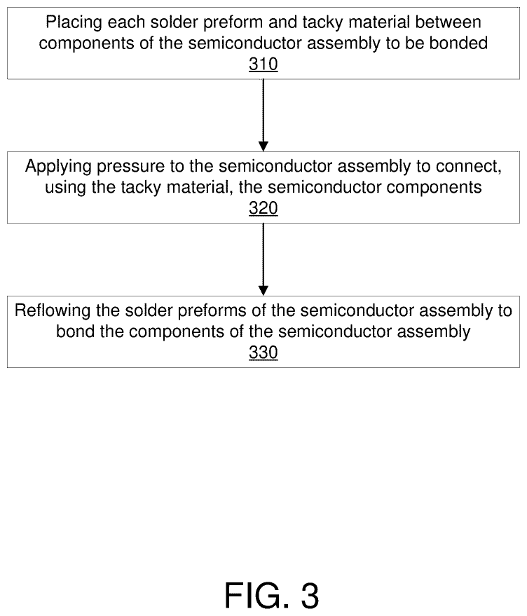

FIG. 3 is an operational flow diagram illustrating an example method of assembling a semiconductor assembly (e.g., semiconductor assembly 600) with one or more solder preforms and a tacky material, in accordance with some implementations of the disclosure. Operation 310 includes placing each solder preform and the tacky material between components of the semiconductor assembly to be bonded. The tacky material can be applied or otherwise dispensed on the surface(s) of the solder preform(s) and/or the surfaces of the semiconductor components that the solder preform(s) are placed on. Prior to placement of each solder preform, the tacky material can be applied on the surfaces of both the solder preform and the semiconductor component, just the surface of the semiconductor component, or just the surface of the solder preform. In some implementations, the tacky material can be used to pre-attach at least some of the solder preforms to respective semiconductor component for later assembly and reflow of the semiconductor package. Any suitable method can be used to dispense or otherwise apply the tacky material on a surface, including screen printing, spin coating, jetting, brushing, etc.

As an example, when assembling semiconductor assembly 600, a first solder preform 300 and tacky material 200 can be placed between the backside of semiconductor chip 100 and the first side of DBC 400, and a second solder preform 350 and tacky material 200 can be placed between DBC 400 and baseplate 500. More particularly, tacky material 200 can be deposited onto the backside of semiconductor die 100 and/or a first side of solder preform 300, and the backside of die 100 can then be placed in proximity to the first side of solder preform 300 such that tacky material 200 is in touching relation with the backside of semiconductor die 100 and the first side of solder preform 300. Tacky material 200 can then be deposited onto the second side of solder preform 300, opposite the first side affixed to the semiconductor die 100, and/or the first side of DBC 400, and the first side of DBC 400 can be placed in proximity to the second side of solder preform such that the tacky material 200 is in touching relation with the second side of solder preform 300 and the first side of DBC 400. Tacky material 200 can then be deposited onto the first side of solder preform 350 and/or the second side of DBC 400 opposite the first side affixed to solder preform 300, and the first side of solder preform 350 can be placed in proximity to the second side of DBC 400 such that tacky material 200 is in touching relation with the first side of solder preform 350 and the second side of DBC 400. Tacky material 200 can then be deposited onto the second side of solder preform 350, opposite the first side affixed to the DBC 400, and/or the first side of baseplate 500, and the first side of baseplate 500 can be placed in proximity to the second side of solder preform 350 such that the tacky material 200 is in touching relation with the second side of solder preform 350 and the first side of baseplate 500.

Operation 320 includes applying pressure to the assembly to connect, using the tacky material, the semiconductor components. For example, during assembly of semiconductor assembly 600, pressure can be applied to connect, using tacky material 200, semiconductor chip 100 to the first side of solder preform 300, the second side of solder preform 300 to the first side of DBC 400, the second side of DBC 400 to the first side of solder preform 350, and the second side of solder preform 350 to the first side of baseplate 500.

Operation 330 includes reflowing the solder preforms of the semiconductor assembly to bond the components of the semiconductor assembly together. For example, semiconductor assembly 600 can be placed into an oven to reflow the first and second solder preforms 300 and 350 to metallurgically bond the semiconductor assembly 600 together. The semiconductor assembly can be placed into an inert or reducing atmospheric oven. The inert or reducing atmosphere can be comprised of nitrogen, argon, helium, hydrogen, formic acid, forming gas, or combinations thereof. During reflow, the tacky material can hold the parts of the semiconductor assembly in place, ensuring proper alignment of the components, and obviating the need for mechanical fixturing to hold the assembly together.

The reflow temperature can be greater than the solidus point of the one or more solder preforms. In a particular implementation, the semiconductor assembly is exposed to a heat source of 230° C. or greater for 20 seconds to 240 seconds. Following the exposure of the assembly to a heat source greater than the solidus point of the solder preform(s), the assembly can be metallurgically bonded. The solder preforms of the assembly can contain no flux coating on their surface or a low-residue flow coating on their surface.

As such, by virtue of utilizing a tacky material 200 to hold the individual parts of semiconductor assembly 600 in place during reflow, proper alignment of the components of semiconductor assembly 600 can be ensured, and need for mechanical fixturing can be eliminated. Employing tacky material 200 in place of bulky fixturing can greatly improve the throughput of devices sent through the reflow oven in a given amount of time. In some implementations, tacky material 200 can be formulated such that it is completely consumed during the reflow process, leaving semiconductor assembly 600 free of any tacky material-related residue.

Because the tacky material 200 can eliminate the need for mechanical fixturing during reflow, the reducing atmospheric gas can easily penetrate the fixtureless-assembly 600 to clean the oxides from the surfaces to be joined during the reflow process. This in turn can eliminate the need for a liquid flux coating on solder preforms 300 and 350. Reflowing the assembly 600 in the absence of flux or with an ultra-low residue flux can reduce or eliminate the need for washing the assembly 600 to remove any flux residue following reflow, and eliminate the many other aforementioned problems associated with flux residues.

In some implementations, the adhesive material described herein can be leveraged to pre-attach solder preforms to components of the semiconductor device prior to final package assembly. In particular, by leveraging this adhesive material technology described herein, substrates, preforms, and other device components can be pre-attached in a package to be assembled at a later time, simplifying the final manufacturing process.

Indium-Braid-Indium TIM

In some implementations, a semiconductor assembly can be assembled using an indium-braid-indium TIM, which can be manufactured in the form of a foil. The thermally conductive indium-braid-indium TIM could be used in place of the solder preforms to assemble the semiconductor assembly. One such example of a foil is described with reference to U.S. Pat. Nos. 4,968,550 and 5,052,611. The thermally conductive foil can be assembled as follows. A braid, i.e. a sheet of braided or woven filaments of metal, glass, or polymeric fibers can be suitably cleaned and pretreated, and coated with upper and lower layers of indium ribbon. The assembly of the braid with the upper and lower indium ribbons can be worked between upper and lower pressure rollers to produce an indium/braid/indium sandwich. The resulting sandwich is of thickness that can be greater than, equal to, or less than that of the original braid. The indium of the ribbons can be self-welding. That is, the working of the material between the rollers flows the indium through voids and interstices between filaments of the braid, and then unites the indium from the ribbon with the indium from the ribbon. This completely buries the filaments in indium. The sandwich can have smooth indium faces. Also, when the sandwich is cut, the indium flows at the edges to cover any filament ends at the edges. The indium braid sandwich can be employed as a conductive foil tape.

The thermally conductive foil could be pre-attached at one of the TIM locations in the semiconductor assembly. It could be pre-attached using a tacky material (e.g., tacky material 200) or attached with pressure alone, taking advantage of the stickiness of indium. The thermally conductive foil would not be reflowed, but attached via pressure. In implementations where the tacky material is used in combination with the thermally conductive, since it is not reflowed, the tacky material residue would remain while the device is in service.

### Sintering

In some implementations, the tacky material described herein could be used in combination with a sintering paste to sinter a semiconductor assembly. The sintering paste can comprise a solvent along with metal sintering particles such as silver particles, copper particles, or some combination thereof. The sintering paste could also comprise spacer particles having an average particle size or diameter within a targeted bond line thickness range. Particular examples of sintering pastes that could be used in combination with a tacky material are described with reference to U.S. patent application Ser. No. 15/460,023, incorporated herein by reference.

For example, a sintering paste could be formed by combining spacer particles with Ag particles and a solvent such that the spacer particles make up between greater than 0 wt % and less than 4 wt % of the combination. The Ag particles may have an average particle size or diameter from 10 nm to 100 um. The Ag particles may make up between 50 wt % and 95 wt % of the sintering paste mixture. The solvent may be a polyglycol solvent or other suitable sintering solvent.

A targeted bond line thickness range could be achieved by adding spacer particles having an average particle size or diameter within the targeted bond line thickness range. The targeted bond line thickness of a silver joint may be between 30 μm and 500 μm. In preferred embodiments, the bond line thickness is from 50 μm to 300 μm, and more particularly, from 60 μm to 100 μm.

The spacer particles can be single composition metal particles such as gold, silver, or copper. In alternative implementations, the spacer particles are provided by way of a solder ball. In these implementations, the solder ball may be a Sn—Pb or no lead solder ball such as, for example Sn—Ag—Cu solder balls such as SAC 105, SAC 205, SAC 305, SAC 387, and the like. In further implementations, the spacer particles are inorganic particles such as boron nitride (BN), silica (SiO2), aluminium oxide (Al2O3), and the like.

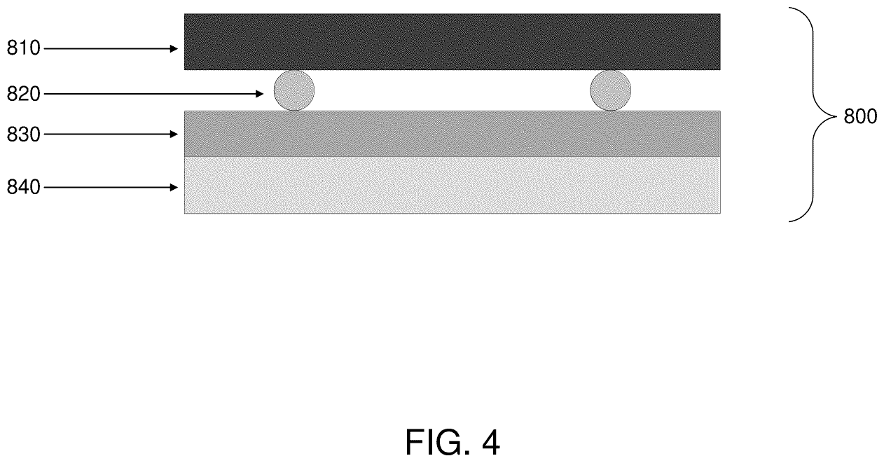

FIG. 4 shows an example side view of a semiconductor assembly 800 that bonds semiconductor die 810 to substrate 840 using a sintering paste 830 and tacky material 820. During assembly, the sintering paste 830 could be deposited (e.g., printed) onto substrate 840. The sintering paste 830 could then be left to dry for a sufficient amount of time (e.g., about 30minutes) at a sufficient temperature (e.g., about 40° C.). Tacky material 820 could be added onto the dried sintering paste 830. Thereafter, semiconductor die 810 could be placed onto tacky material 820 to hold the die in place. The sintering paste 830 could be sintered at about room temperature (e.g., about 25° C.) using pressure only (no heat) to form a joint between the die 810 and substrate 840. In some implementations, the assembly is sintered at a pressure between 5 and 35 psi. In implementations, pressure may be applied using a pick and place tool. In the case of sintering at room temperature, tacky material residue may remain while the device is in service. In some implementations, the assembly may be sintered at a target sintering temperature and subsequently cooled down.

One advantage of using a tacky material as described above in a sintering process is that it can avoid the defect risks associated with potential movement/misalignment of the semiconductor components after sintering paste 830 dries but before pressure is applied to the assembly. This movement of the components can be caused by normal handling of the components, including, for example, transit on a conveyor. The sintering paste, by itself, will not prevent this movement before pressure is applied to sinter the components together. By employing a tacky material 820 to adhere the components together, the risk associated with potential movement of components is obviated.

While various embodiments of the disclosed technology have been described above, it should be understood that they have been presented by way of example only, and not of limitation. Likewise, the various diagrams may depict an example architectural or other configuration for the disclosed technology, which is done to aid in understanding the features and functionality that can be included in the disclosed technology. The disclosed technology is not restricted to the illustrated example architectures or configurations, but the desired features can be implemented using a variety of alternative architectures and configurations. Additionally, with regard to flow diagrams, operational descriptions and method claims, the order in which the steps are presented herein shall not mandate that various embodiments be implemented to perform the recited functionality in the same order unless the context dictates otherwise.

Although the disclosed technology is described above in terms of various exemplary embodiments and implementations, it should be understood that the various features, aspects and functionality described in one or more of the individual embodiments are not limited in their applicability to the particular embodiment with which they are described, but instead can be applied, alone or in various combinations, to one or more of the other embodiments of the disclosed technology, whether or not such embodiments are described and whether or not such features are presented as being a part of a described embodiment. Thus, the breadth and scope of the technology disclosed herein should not be limited by any of the above-described exemplary embodiments.

Terms and phrases used in this document, and variations thereof, unless otherwise expressly stated, should be construed as open ended as opposed to limiting. As examples of the foregoing: the term “including” should be read as meaning “including, without limitation” or the like; the term “example” is used to provide exemplary instances of the item in discussion, not an exhaustive or limiting list thereof; the terms “a” or “an” should be read as meaning “at least one,” “one or more” or the like; and adjectives such as “conventional,” “traditional,” “normal,” “standard,” “known” and terms of similar meaning should not be construed as limiting the item described to a given time period or to an item available as of a given time, but instead should be read to encompass conventional, traditional, normal, or standard technologies that may be available or known now or at any time in the future. Likewise, where this document refers to technologies that would be apparent or known to one of ordinary skill in the art, such technologies encompass those apparent or known to the skilled artisan now or at any time in the future.

The presence of broadening words and phrases such as “one or more,” “at least,” “but not limited to” or other like phrases in some instances shall not be read to mean that the narrower case is intended or required in instances where such broadening phrases may be absent.

Additionally, the various embodiments set forth herein are described in terms of exemplary block diagrams, flow charts and other illustrations. As will become apparent to one of ordinary skill in the art after reading this document, the illustrated embodiments and their various alternatives can be implemented without confinement to the illustrated examples. For example, block diagrams and their accompanying description should not be construed as mandating a particular architecture or configuration.

It should be appreciated that all combinations of the foregoing concepts (provided such concepts are not mutually inconsistent) are contemplated as being part of the inventive subject matter disclosed herein. In particular, all combinations of claimed subject matter appearing in this disclosure are contemplated as being part of the inventive subject matter disclosed herein.

What is claimed is:

1. A method, comprising:
placing a first solder preform and a first tacky material between a first device and a second device to form a semiconductor assembly, the first tacky material configured to cause a surface of the first device to adhere to a first surface of the first solder preform, and a first surface of the second device to adhere to a second surface of the first solder preform opposite the first surface; and
reflowing the semiconductor assembly at a temperature above a solidus temperature of the first solder preform to bond, via at least the first solder preform, the first device to the second device, wherein the first tacky material has a reflow residual weight of less than 1% of a weight of the first tacky material before reflowing the semiconductor assembly.

2. The method of claim 1, wherein:
the first device is a semiconductor die; and
the first tacky material is placed between the first solder preform and the semiconductor die.

3. The method of claim 2 wherein:
the second device is a DBC or baseplate; and
and the first tacky material is placed between the first solder preform and the DBC or baseplate.

4. The method of claim 1, wherein:
the first device is a DBC; and
the first tacky material is placed between the first solder preform and the DBC.

5. The method of claim 1, wherein:
the first device is a baseplate; and
the first tacky material is placed between the first solder preform and the baseplate.

6. The method of claim 1, further comprising: prior to reflowing the semiconductor assembly, applying pressure to the semiconductor assembly to cause the surface of the first device to adhere, via the first tacky material, to the first surface of the first solder preform, and the surface of the second device to adhere, via the first tacky material, to the second surface of the solder preform.

7. The method of claim 6, wherein reflowing the semiconductor assembly comprises:
reflowing the semiconductor assembly without a mechanical fixture that holds together the semiconductor assembly.

8. The method of claim 7, wherein reflowing the semiconductor assembly comprises heating the semiconductor assembly in the presence of an inert gas or reducing gas.

9. The method of claim 8, wherein the inert gas or reducing gas comprises nitrogen, argon, helium, hydrogen, formic acid, or forming gas.

10. The method of claim 6, wherein reflowing the semiconductor assembly comprises heating the first solder preform above its solidus point to metallurgically bond the semiconductor assembly.

11. The method of claim 10, wherein reflowing the semiconductor assembly comprises exposing the semiconductor assembly to a heat source of 230° C. or greater for 20 seconds to 240 seconds.

12. The method of claim 1, wherein the reflow residual weight of the first tacky material is less than 0.1% of the weight of the first tacky material before reflowing the semiconductor assembly.

13. The method of claim 10, the first tacky material is fully consumed during reflow of the semiconductor assembly.

14. The method of claim 1, wherein the first tacky material has a viscosity from 6 Kcps to 30 Kcps.

15. The method of claim 1, wherein the first tacky material has a tackiness from 260 grams to 410 grams.

16. The method of claim 1, wherein reflowing the semiconductor assembly comprises:
reflowing the semiconductor assembly without a flux coating on the first solder preform.

17. The method of claim 1, wherein reflowing the semiconductor assembly comprises:
reflowing the semiconductor assembly with a low-residue flux coating on the first solder preform.

18. The method of claim 1, wherein the first solder preform comprises an interior matrix material having a solidus point higher than a solidus point of the first solder preform.

19. The method of claim 18, wherein the interior matrix material comprises copper or silver.

20. The method of claim 18, wherein the solidus point of the interior matrix material is at least 100°° C. greater than the solidus point of the first solder preform.

21. The method of claim 18, wherein the solidus point of the interior matrix material is at least 500° C. greater than the solidus point of the first solder preform.

22. The method of claim 18, wherein the interior matrix material comprises a coating.

23. The method of claim 1, wherein the first solder preform comprises tin, silver, copper, antimony, lead, or indium.

24. The method of claim 1, further comprising: placing a second solder preform and a second tacky material between the second device and a third device to form the semiconductor assembly, the second tacky material configured to cause a second surface of the second device opposite the first surface of the second device to adhere to a first surface of the second solder preform, and a first surface of third device to adhere to a second surface of the second solder preform opposite the first surface of the second solder preform.

25. The method of claim 24, wherein:
reflowing the semiconductor assembly comprises reflowing the semiconductor assembly at a temperature above the solidus temperature of the first solder preform and above a solidus temperature of the second solder preform to bond, via at least the first solder preform, the first device to the second device, and to bond, via at least the second solder preform, the second device to the third device; and
the second tacky material has a reflow residual weight of less than 1% of a weight of the second tacky material before reflowing the semiconductor assembly.

26. A method, comprising:
dispensing a sintering paste on a substrate, the sintering paste comprising a plurality of silver particles or copper particles;
after dispensing the sintering paste, drying the sintering paste to form a dried sintering paste;
depositing a tacky material on the dried sintering paste;
after depositing the tacky material on the dried sintering paste, placing a device on the tacky material to form a semiconductor assembly; and
sintering the semiconductor assembly to form a sintering joint bonding the substrate and device.

27. A method, comprising:
applying a thermal interface material (TIM) between a first device and a second device to form a semiconductor assembly having a first surface of the TIM in in touching relation with a surface of the first device, and a second surface of the TIM opposite the first surface in touching relation with a surface of the second device, the TIM comprising a flexible sheet material including a braid layer formed of a plurality of filaments of metal, glass, or polymeric fibers, and first and second layers of indium impressed directly against the braid layer with the braid layer sandwiched therebetween; and
applying pressure to the semiconductor assembly to bond, via the flexible sheet material, the first device to the second device.
